(19) United States
(12) Patent Application Publication
(10) Pub. No.: US 2023/0131382 A1
(43) Pub. Date: Apr. 27, 2023

(54) THREE-DIMENSIONAL INTEGRATED CIRCUIT STRUCTURE AND METHOD OF MANUFACTURING THE SAME

(71) Applicant: SAMSUNG ELECTRONICS CO., LTD., Suwon-si (KR)

(72) Inventors: Shaofeng DING, Suwon-si (KR); Jihyung KIM, Seoul (KR); Won Ji PARK, Suwon-si (KR); Jeong Hoon AHN, Seongnam-si (KR); Jaehee OH, Seongnam-s (KR); Yun Ki CHOI, Yongin-si (KR)

(73) Assignee: SAMSUNG ELECTRONICS CO., LTD., Suwon-si (KR)

(21) Appl. No.: 17/843,594

(22) Filed: Jun. 17, 2022

(30) Foreign Application Priority Data
Oct. 26, 2021 (KR) 10-2021-0143894

(51) Int. Cl. H01L 27/06; H01L 25/07; H01L 27/02

(52) U.S. Cl. CPC H01L 27/0694; H01L 25/074; H01L 27/0248

(57) ABSTRACT

Disclosed is a three-dimensional integrated circuit structure including an active device die and a capacitor die stacked on the logic die. The active device die includes: a first substrate including a front side and a back side that are opposite to each other; a power delivery network on the back side of the first substrate; a device layer on the front side of the first substrate; a first wiring layer on the device layer; and a through contact that vertically extends from the power delivery network to the first wiring layer. The passive device die includes: a second substrate including a front side and a back side that are opposite to each other, the front side of the second substrate facing the front side of the first substrate; an interlayer dielectric layer on the front side of the second substrate, the interlayer dielectric layer including at least one hole; a passive device in the hole; and a second wiring layer on the passive device, wherein the second wiring layer faces and is connected to the first wiring layer.

### CROSS-REFERENCE TO RELATED APPLICATION

This application claims priority from Korean Patent Application No. 10-2021-0143894 filed on Oct. 26, 2021 in the Korean Intellectual Property Office, the disclosure of which is incorporated herein in its entirety by reference.

### BACKGROUND

The embodiments of the disclosure relate to a three-dimensional integrated circuit structure and a method of manufacturing the same, and more particularly, to a three-dimensional integrated circuit structure with improved electrical properties and a method of manufacturing the same.

In the semiconductor industry, high capacity, thinness, and small size of semiconductor devices and electronic products using the same have been demanded and thus various packaging technologies have been suggested. A semiconductor package is provided to implement an integrated circuit chip to qualify for use in electronic products. A semiconductor package is typically configured such that a semiconductor chip is mounted on a printed circuit board (PCB) and bonding wires or bumps are used to electrically connect the semiconductor chip to the printed circuit board. With the development of electronic industry, electronic products have increasingly demands for high performance, high speed, and compact size.

### SUMMARY

Example embodiments provide a three-dimensional integrated circuit structure with improved electrical properties.

The embodiments also provide a method of fabricating a three-dimensional integrated circuit structure with improved electrical properties.

According to embodiments, a three-dimensional integrated circuit structure may include: an active device die and a passive device die stacked on the active device die. The active device die may include: a first substrate including a front side and a back side that are opposite to each other; a power delivery network on the back side of the first substrate; a device layer on the front side of the first substrate; a first wiring layer on the device layer; and a through contact that vertically extends from the power delivery network to the first wiring layer. The passive device die may include: a second substrate including a front side and a back side that are opposite to each other, the front side of the second substrate facing the front side of the first substrate; an interlayer dielectric layer on the front side of the second substrate, the interlayer dielectric layer including at least one hole; a passive device in the hole; and a second wiring layer on the passive device, wherein the second wiring layer faces and is connected to the first wiring layer.

According to embodiments, a three-dimensional integrated circuit structure may include: a first die including a power delivery network, a first substrate, a device layer, and a first wiring layer that are sequentially stacked; a second die on the first die, the second die including a second wiring layer, a capacitor layer, and a second substrate that are sequentially stacked on the first wiring layer; a through contact that vertically extends from the power delivery network to the first wiring layer; and an external connection member beneath the power delivery network. A lower portion of the through contact may be in contact with a lower line of the power delivery network. An upper portion of the through contact may be in contact with a power line of the first wiring layer. A width of the lower portion of the through contact may be greater than a width of the upper portion of the through contact. A power may be vertically transmitted from the external connection member to the capacitor layer through the power delivery network, the through contact, the first wiring layer, and the second wiring layer.

According to embodiments, a three-dimensional integrated circuit structure may include: a power delivery network that includes a plurality of stacked lower lines; a first semiconductor substrate on the power delivery network; a plurality of transistors that are on the first semiconductor substrate and constitute a logic circuit; a first wiring layer that includes a plurality of metal layers on the plurality of transistors; a through contact that electrically connects the power delivery network to a first metal layer of the plurality of metal layers, the through contact penetrating the first semiconductor substrate and vertically extending; a second wiring layer on the first wiring layer; a capacitor layer on the second wiring layer, the capacitor layer including an interlayer dielectric layer and a capacitor that penetrates the interlayer dielectric layer; and a second semiconductor substrate on the capacitor layer. The plurality of transistors and the capacitor may be electrically connected to each other through the first and second wiring layers.

### BRIEF DESCRIPTION OF THE DRAWINGS

FIG. 1 illustrates a plan view showing a logic die according to embodiments.

FIGS. 2A, 2B, 2C, 2D, and 2E illustrate cross-sectional views respectively taken along lines A-A′, B-B′, C-C′, D-D′, and E-E′ of FIG. 1.

FIG. 3 illustrates a cross-sectional view showing a semiconductor package according to embodiments.

FIG. 4 illustrates an enlarged cross-sectional view of section M shown in FIG. 3, showing a three-dimensional integrated circuit structure according to embodiments.

FIGS. 5 to 8 illustrate cross-sectional views of section M shown in FIG. 3, showing a method of fabricating a three-dimensional integrated circuit structure, according to embodiments.

FIGS. 9A, 9B, 9C, 9D, and 9E illustrate cross-sectional views respectively taken along lines A-A′, B-B′, C-C′, D-D′, and E-E′ of FIG. 1, showing a logic die according to embodiments.

### DETAIL PARTED DESCRIPTION OF EMBODIMENTS

The embodiments described herein are example embodiments, and thus, the disclosure is not limited thereto and may be realized in various other forms.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present. Spatially relative terms, such as “over,” “above,” “on,” “upper,” “below,” “under,” “beneath,” “lower,” and the like, may be used herein for ease of description to describe one element's or feature's relationship to another element(s) or feature(s) as illustrated in the figures.

It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

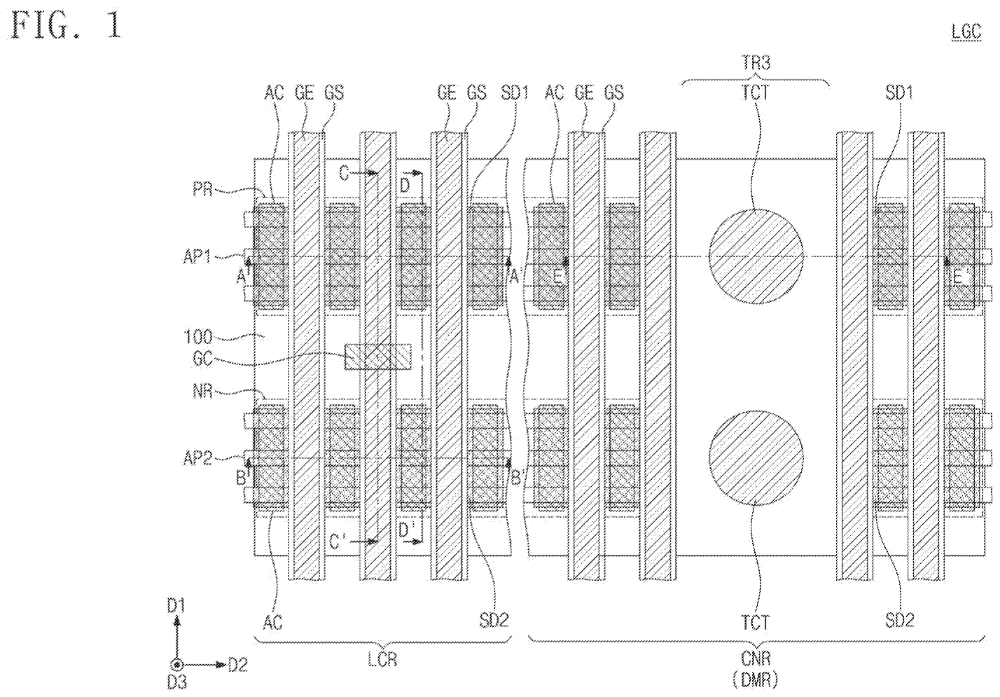

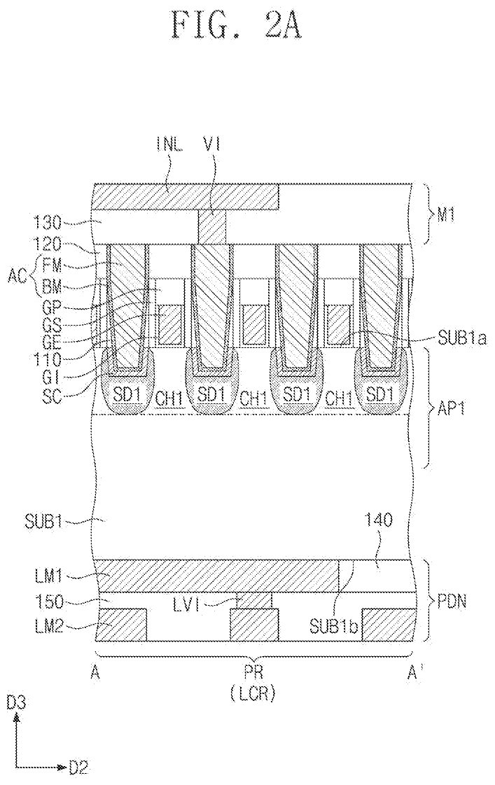

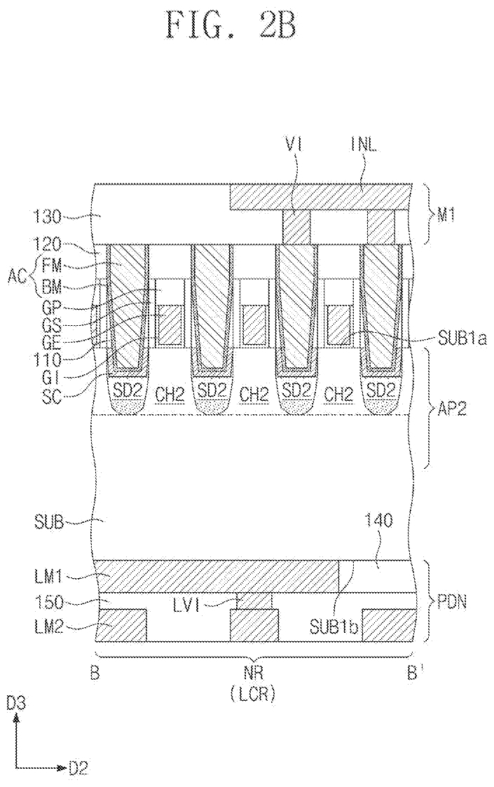

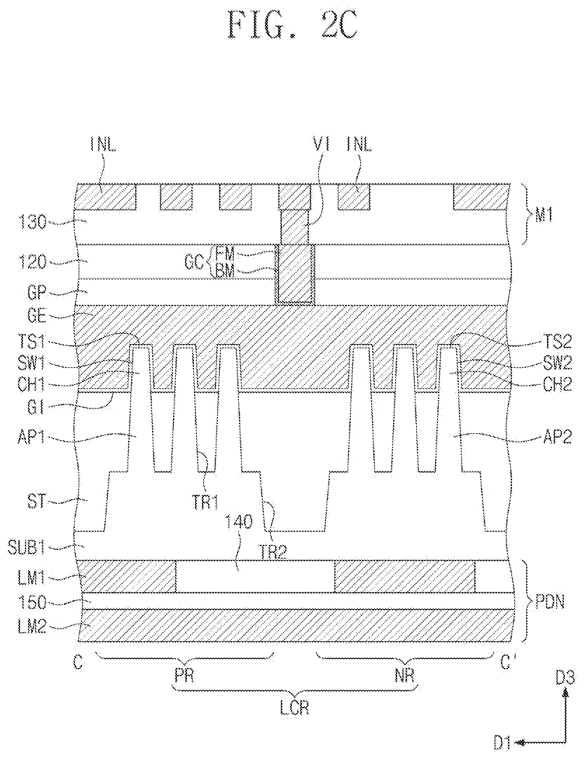

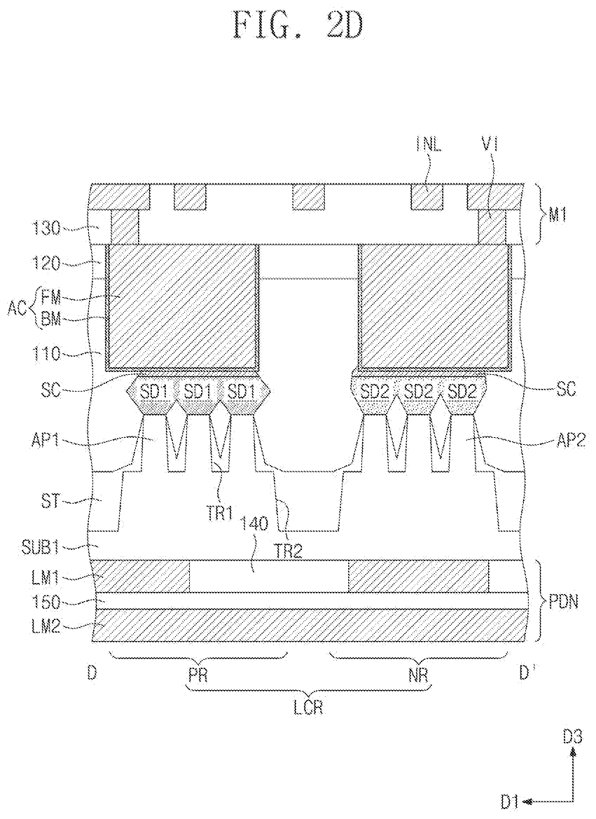

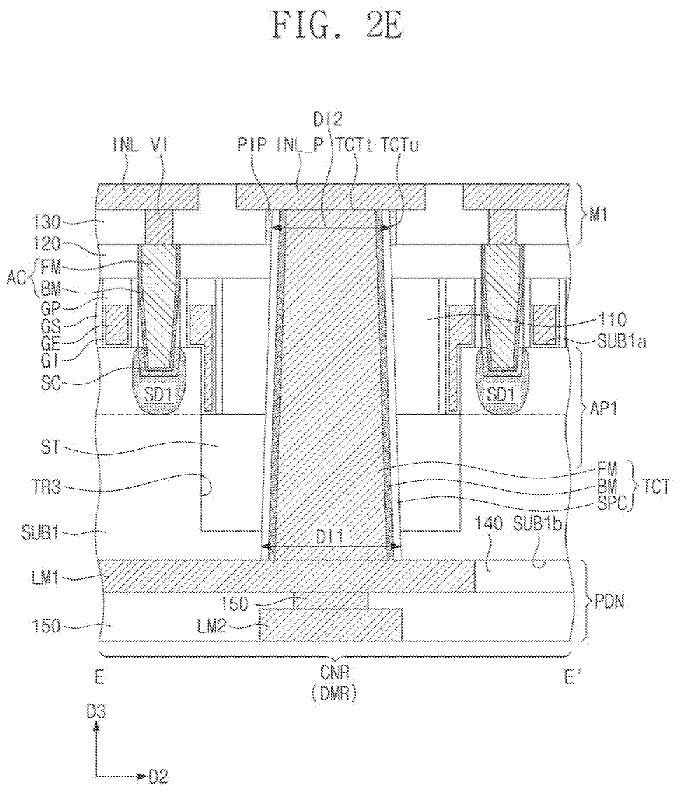

FIG. 1 illustrates a plan view showing a logic die according to embodiments. FIGS. 2A, 2B, 2C, 2D, and 2E illustrate cross-sectional views respectively taken along lines A-A′, B-B′, C-C′, D-D′, and E-E′ of FIG. 1.

Referring to FIGS. 1 and 2A to 2E, a logic die LGC may include a logic cell region LCR and a connection region CNR on a first substrate SUB1. The logic cell region LCR may include a logic cell (or standard cell) that constitutes a logic circuit. As known in the art, the logic circuit may include combinational logic and sequential logic circuit elements defined by Boolean logic expressions made up of basic logic gates (AND, OR, etc.). Examples of the logic circuit are not limited to multiplexer, register, arithmetic logic unit, and memory. The logic cell region LCR illustrated in FIG. 1 may show by way of example one of a plurality of logic cells. At least one through contact TCT may be provided on the connection region CNR.

The following will describe in detail the logic cell region LCR with reference to FIGS. 1 and 2A to 2D. The first substrate SUB1 may have a first surface SUB1a and a second surface SUB1b that are opposite to each other. The first surface SUB1a may be a top surface or a front side of the first substrate SUB1, and the second surface SUB1b may be a bottom surface or a back side of the first substrate SUB1.

A device layer may be provided on the first surface SUB1a of the first surface SUB1a. The first substrate SUB1 may include a first active region PR and a second active region NR. In embodiments, the first active region PR may be a p-type metal-oxide-semiconductor field-effect transistor (PMOSFET) region, and the second active region NR may be an n-type metal-oxide-semiconductor field-effect transistor (NMOSFET) region. The first substrate SUB1 may be a compound semiconductor substrate or a semiconductor substrate including silicon, germanium, or silicon-germanium. For example, the first substrate SUB1 may be a silicon substrate.

The first active region PR and the second active region NR may be defined by a second trench TR2 formed on an upper portion of the first substrate SUB1. The second trench TR2 may be disposed between the first active region PR and the second active region NR. The first and second active regions PR and NR may be spaced apart from each other in a first direction D1 across the second trench TR2. Each of the first and second active regions PR and NR may extend in a second direction D2 that intersects the first direction D1.

First active patterns AP1 and second active patterns AP2 may be respectively provided on the first active region PR and the second active region NR. The first and second active patterns AP1 and AP2 may extend in parallel to each other in the second direction D2. The first and second active patterns AP1 and AP2 may be vertically protruding portions of the first substrate SUB1. A first trench TR1 may be defined between neighboring first active patterns AP1 and between neighboring second active patterns AP2. The first trench TR1 may be shallower than the second trench TR2.

A device isolation layer ST may fill the first and second trenches TR1 and TR2. The device isolation layer ST may include a silicon oxide layer. The first and second active patterns AP1 and AP2 may have their upper portions that vertically protrude above a level of a top surface of the device isolation layer ST (see FIG. 2C). Each of the first and second active patterns AP1 and AP2 may have a fin shape at the upper portion thereof. The device isolation layer ST may not be formed on the upper portions of the first and second active patterns AP1 and AP2. The device isolation layer ST may be formed on lower sidewalls of the first and second active patterns AP1 and AP2.

The first active patterns AP1 may have first source/drain patterns SD1 formed on the upper portions thereof. The first source/drain patterns SD1 may be impurity regions having a first conductivity type (e.g., p-type). A first channel pattern CH1 may be interposed between a pair of first source/drain patterns SD1. The second active patterns AP2 may have second source/drain patterns SD2 formed on the upper portions thereof. The second source/drain patterns SD2 may be impurity regions having a second conductivity type (e.g., n-type). A second channel pattern CH2 may be interposed between a pair of second source/drain patterns SD2.

The first and second source/drain patterns SD1 and SD2 may be epitaxial patterns formed by a selective epitaxial growth process. For example, the first and second source/drain patterns SD1 and SD2 may have their top surfaces coplanar with those of the first and second channel patterns CH1 and CH2. For another example, the first and second source/drain patterns SD1 and SD2 may have their top surfaces formed higher than a level of those of the first and second channel patterns CH1 and CH2.

The first source/drain patterns SD1 may include a semiconductor element (e.g., SiGe) whose lattice constant is greater than that of a semiconductor element of the first substrate SUB1. Therefore, the first source/drain patterns SD1 may provide the first channel patterns CH1 with compressive stress. According to an embodiment, the second source/drain patterns SD2 may include the same semiconductor element (e.g., Si) as that of the first substrate SUB1.

There may be provided gate electrodes GE that extend in the first direction D1 while running across the first and second active patterns AP1 and AP2. The gate electrodes GE may be arranged along the second direction D2 at a regular pitch. The gate electrodes GE may vertically overlap the first and second channel patterns CH1 and CH2. Each of the gate electrodes GE may surround a top surface and opposite sidewalls of each of the first and second channel patterns CH1 and CH2.

Referring back to FIG. 2C, the gate electrode GE may be provided on a first top surface TS1 of the first channel pattern CH1 and on at least one first sidewall SW1 of the first channel pattern CH1. The gate electrode GE may be provided on a second top surface TS2 of the second channel pattern CH2 and on at least one second sidewall SW2 of the second channel pattern CH2. According to an embodiment, a transistor according to the present embodiment may be a three-dimensional field effect transistor (e.g., FinFET) in which the gate electrode GE three-dimensionally surrounds the first and second channel patterns CH1 and CH2.

Referring back to FIGS. 1 and 2A to 2D, a pair of gate spacers GS may be disposed on opposite sidewalls of each of the gate electrodes GE. The gate spacers GS may extend in the first direction D1 along the gate electrodes GE. The gate spacers GS may have their top surfaces higher than a level of those of the gate electrodes GE. The top surfaces of the gate spacers GS may be coplanar with that of a first interlayer dielectric layer 110 which will be discussed below. The gate spacers GS may include at least one of SiCN, SiCON, and SiN. Alternatively, the gate spacers GS may each include a multiple layer formed of at least two of SiCN, SiCON, and SiN.

A gate capping pattern GP may be provided on each of the gate electrodes GE. The gate capping pattern GP may extend in the first direction D1 along the gate electrode GE. The gate capping pattern GP may include a material having an etch selectivity with respect to first and second interlayer dielectric layers 110 and 120 which will be discussed below. For example, the gate capping patterns GP may include at least one of SiON, SiCN, SiCON, and SiN.

A gate dielectric layer GI may be interposed between the gate electrode GE and the first active pattern AP1 and between the gate electrode GE and the second active pattern AP2. The gate dielectric layer GI may extend along a bottom surface of the gate electrode GE that overlies the gate dielectric layer GI. For example, the gate dielectric layer GI may be formed on the first top surface TS1 and the first sidewall SW1 of the first channel pattern CH1. The gate dielectric layer GI may be formed on the second top surface TS2 and the second sidewall SW2 of the second channel pattern CH2. The gate dielectric layer GI may be formed on a top surface of the device isolation layer ST that underlies the gate electrode GE (see FIG. 2C).

In embodiments, the gate dielectric layer GI may include a high-k dielectric material whose dielectric constant is greater than that of a silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

The gate electrode GE may include a first metal pattern and a second metal pattern on the first metal pattern. The first metal pattern may be provided on the gate dielectric layer GI and may be adjacent to the first and second channel patterns CH1 and CH2. The first metal pattern may include a work-function metal that controls a threshold voltage of a transistor. A thickness and composition of the first metal pattern may be adjusted to achieve a desired threshold voltage.

The first metal pattern may include a metal nitride layer. For example, the first metal pattern may include nitrogen (N) and at least one of titanium (Ti), tantalum (Ta), aluminum (Al), tungsten (W), and molybdenum (Mo). The first metal pattern may further include carbon (C). The first metal pattern may include a plurality of stacked work-function metal layers.

The second metal pattern may include metal whose resistance is smaller than that of the first metal pattern. For example, the second metal pattern may include at least one of tungsten (W), aluminum (Al), titanium (Ti), and tantalum (Ta).

A first interlayer dielectric layer 110 may be provided on the first substrate SUB1. The first interlayer dielectric layer 110 may be formed on the gate spacers GS and the first and second source/drain patterns SD1 and SD2. The first interlayer dielectric layer 110 may have a top surface substantially coplanar with those of the gate capping patterns GP and those of the gate spacers GS. The first interlayer dielectric layer 110 may be provided thereon with a second interlayer dielectric layer 120 that is formed on the gate capping patterns GP. A third interlayer dielectric layer 130 may be provided on the second interlayer dielectric layer 120. For example, the first, second, and third interlayer dielectric layers 110, 120, and 130 may include a silicon oxide layer.

There may be provided active contacts AC that penetrate the first and second interlayer dielectric layers 110 and 120 to be correspondingly electrically connected to the first and second source/drain patterns SD1 and SD2. Each of the active contacts AC may be provided between two adjacent gate electrodes GE.

The active contact AC may be a self-aligned contact. For example, the gate capping pattern GP and the gate spacer GS may be used to form the active contact AC in a self-alignment manner. The active contact AC may be formed on, for example, at least a portion of a sidewall of the gate spacer GS. Although not shown, the active contact AC may be formed on a portion of the top surface of the gate capping pattern GP.

A silicide pattern SC may be interposed between the active contact AC and the first source/drain pattern SD1 and between the active contact AC and the second source/drain pattern SD2. The active contact AC may be electrically connected through the silicide pattern SC to one of the first and second source/drain patterns SD1 and SD2. The silicide pattern SC may include metal silicide, for example, at least one of titanium silicide, tantalum silicide, tungsten silicide, nickel silicide, and cobalt silicide.

The active contact AC may include a conductive pattern FM and a barrier pattern BM that surrounds the conductive pattern FM. For example, the conductive pattern FM may include at least one of aluminum, copper, tungsten, molybdenum, and cobalt. The barrier pattern BM may be formed on sidewalls and a bottom surface of the conductive pattern FM. The barrier pattern BM may include a metal nitride layer or a combination of metal and metal nitride layers. The metal layer may include at least one of titanium, tantalum, tungsten, nickel, cobalt, and platinum. The metal nitride layer may include at least one of a titanium nitride (TiN) layer, a tantalum nitride (TaN) layer, a tungsten nitride (WN) layer, a nickel nitride (NiN) layer, a cobalt nitride (CoN) layer, and a platinum nitride (PtN) layer.

At least one gate contact GC may be provided to penetrate the second interlayer dielectric layer 120 and the gate capping pattern GP to be electrically connected to the gate electrode GE. When viewed in plan, the gate contact GC may be disposed between the first active region PR and the second active region NR. The gate contact GC may be disposed on the device isolation layer ST that fills the second trench TR2.

The gate contact GC may include a conductive pattern FM and a barrier pattern BM that surrounds the conductive pattern FM. The conductive pattern FM and the barrier pattern BM of the gate contact GC may be respectively identical to the conductive pattern FM and the barrier pattern BM of the active contact AC.

A first metal layer M1 may be provided in the third interlayer dielectric layer 130. The first metal layer M1 may include lines INL and vias VI. The lines INL may be provided in an upper portion of the third interlayer dielectric layer 130, and the vias VI may be provided in a lower portion of the third interlayer dielectric layer 130. The vias VI may be correspondingly provided beneath the lines INL.

For example, the lines INL may extend in parallel to each other in the second direction D2. The lines INL may be arranged along the first direction D1 at a regular pitch. Each of the vias VI may connect the line IL to at least one of the active and gate contacts AC and GC.

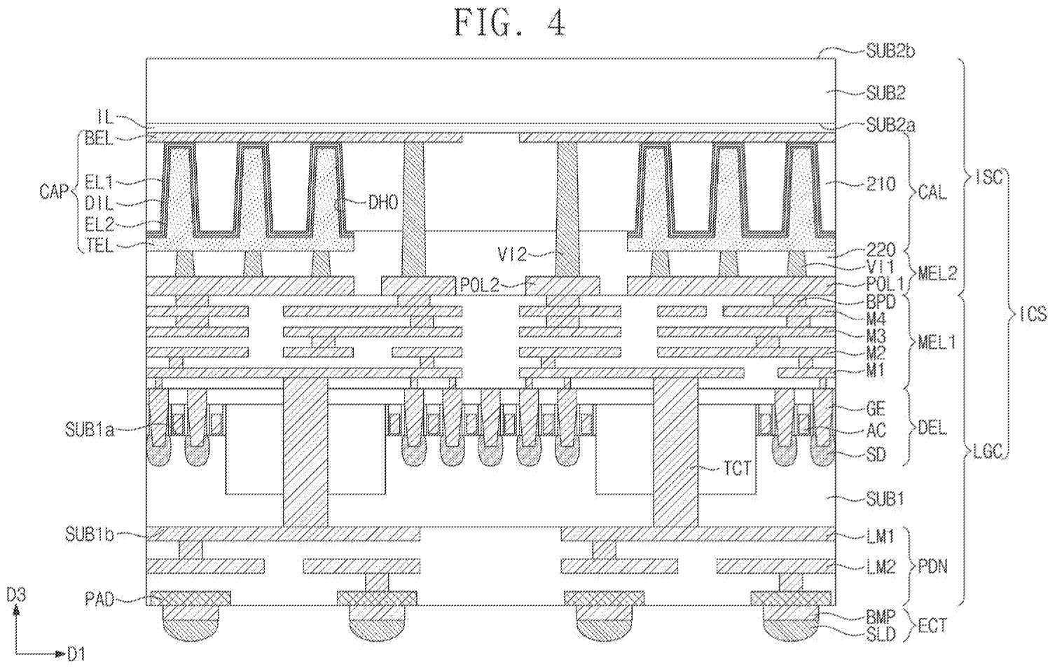

As discussed with reference to FIG. 4, additional metal layer (e.g., M2, M3, M4, etc.) may be stacked on the first metal layer M1. The stacked metal layers may include routing lines that connect logic cells to each other.

A power delivery network PDN may be provided on the second surface SUB1b of the first substrate SUB1. The power delivery network PDN may include a fourth interlayer dielectric layer 140 and a fifth interlayer dielectric layer 150 that are sequentially stacked on the second surface SUB1b of the first substrate SUB1.

The power delivery network PDN may further include first lower lines LM1 and second lower lines LM2. The first lower lines LM1 may be provided in the fourth interlayer dielectric layer 140, and the second lower lines LM2 may be provided in the fifth interlayer dielectric layer 150. A lower via LVI may be provided between the first and second lower lines LM1 and LM2.

The power delivery network PDN may include a wiring network that applies power to a power line of the lines INL in the first metal layer M1. Although not shown in the drawings, lower metal layers may be additionally disposed beneath the fifth interlayer dielectric layer 150.

With reference to FIGS. 1 and 2E, the following will describe in detail the connection region CNR of the logic die LGC. The connection region CNR may include at least one dummy cell region DMR and at least one through contact TCT. The dummy cell region DMR may be a tap cell that applies power from the power delivery network PDN to a power line of the first metal layer M1. Unlike the logic cell region LCR, the dummy cell region DMR may include no logic element. For example, the dummy cell region DMR may have a function that provides a power line with power, but may have no circuit function.

The dummy cell region DMR may have a structure substantially the same as that of the logic cell region LCR discussed above. For example, likewise the logic cell region LCR, the dummy cell region DMR may include a first active region PR, a second active region NR, and a three-dimensional field effect transistor on the first and second active regions PR and NR. Identically to the logic cell region LCR, the dummy cell region DMR may be provided thereon with active contacts AC, gate contacts GC, and a first metal layer M1.

Differently from the logic cell region LCR, the dummy cell region DMR on the connection region CNR may be a dummy that does not constitute a logic circuit. For example, a transistor on the dummy cell region DMR may be a dummy transistor. When no pattern is formed at all on the dummy cell region DMR due to the fact that the dummy cell region DMR does not serve as a substantially useful logic cell, a pattern density of the dummy cell region DMR may be abruptly reduced in a photolithography process for forming the logic cell regions LCR. This may induce defects of the photolithography process. Therefore, processes for forming the logic cell regions LCR may be identically performed on the dummy cell region DMR.

Referring back to FIG. 1, the through contact TCT may be provided spaced apart at a certain distance from the logic cell region LCR. In embodiments, the through contact TCT may be selectively provided on the connection region CNR except the logic cell region LCR (or, on the dummy cell region DMR).

Referring back to FIGS. 1 and 2E, the first substrate SUB1 may have on its upper portion a third trench TR3 that divides the first active pattern AP1 into two parts in the second direction D2. The device isolation layer ST may fill the third trench TR3.

The through contact TCT may be provided to extend in a vertical direction (or a third direction D3) from the power delivery network PDN to the first metal layer M1. The through contact TCT may penetrate the first substrate SUB1 and the device isolation layer ST that fills the third trench TR3. The through contact TCT may be connected to a power line INL_P of the first metal layer M1.

A top surface TCTt of the through contact TCT may be directly connected to a bottom surface of the power line INL_P in the first metal layer M1. A via VI may be omitted between the power line INL_P and the top surface TCTt of the through contact TCT. For example, the through contact TCT and the power line INL_P may be directly connected to each other without the via VI. The through contact TCT may vertically extend from the bottom surface of the power line INL_P in the first metal layer M1 to the second surface SUB1b of the first substrate SUB1.

An upper portion of the through contact TCT may penetrate the third interlayer dielectric layer 130 to rest inside the first metal layer M1. A protection dielectric pattern PIP may be provided on the protruding portion of the through contact TCT. For example, the protection dielectric pattern PIP may be formed on an upper sidewall TCTu of the through contact TCT. The protection dielectric pattern PIP may include at least one of SiN, SiCN, and SiON.

The top surface TCTt of the through contact TCT may be disposed higher than a level of a top surface of the second interlayer dielectric layer 120. The top surface TCTt of the through contact TCT may be disposed at a level between that of a bottom surface of the third interlayer dielectric layer 130 and that of a top surface of the third interlayer dielectric layer 130. The top surface TCTt of the through contact TCT may be disposed at a level substantially the same as that of a top surface of the via VI. The protection dielectric pattern PIP may extend from the top surface of the second interlayer dielectric layer 120 to the bottom surface of the power line INL_P.

The through contact TCT may have a diameter that decreases in a direction from a lower portion toward an upper portion thereof. For example, the through contact TCT may have a first diameter DI1 at its lower portion in contact with the first lower line LM1 of the power delivery network PDN. The through contact TCT may have a second diameter DI2 at its upper portion in contact with the power line INL_P of the first metal layer M1. The second diameter DI2 may be smaller than the first diameter DI1. According to an embodiment, the first and second diameters DI1 and DI2 may represent first and second widths of the through contact TCT in the D2 direction.

The through contact TCT may include a conductive pattern FM, and may also include a barrier pattern BM and a dielectric spacer SPC that are formed on the conductive pattern FM. The conductive pattern FM may have a pillar shape that vertically extends. The barrier pattern BM may be formed on an outer sidewall of the conductive pattern FM. The barrier pattern BM may expose top and bottom surfaces of the conductive pattern FM. The dielectric spacer SPC may be formed on an outer sidewall of the barrier pattern BM.

The conductive pattern FM may include at least one of aluminum, copper, tungsten, molybdenum, and cobalt. The barrier pattern BM may include a metal nitride layer or a combination of metal and metal nitride layers. The metal nitride layer may include at least one of a titanium nitride (TiN) layer, a tantalum nitride (TaN) layer, a tungsten nitride (WN) layer, a nickel nitride (NiN) layer, a cobalt nitride (CoN) layer, and a platinum nitride (PtN) layer.

Power may be transferred via the through contact TCT from the power delivery network PDN on the second surface SUB1b of the first substrate SUB1 to the power line INL_P on the first surface SUB1a of the first substrate SUB1. The power delivered to the power line INL_P may be transferred through the active contact AC to a transistor of the logic cell region LCR. For example, through contact TCT may vertically transfer the power from the power delivery network PDN to a device layer on the first surface SUB1a.

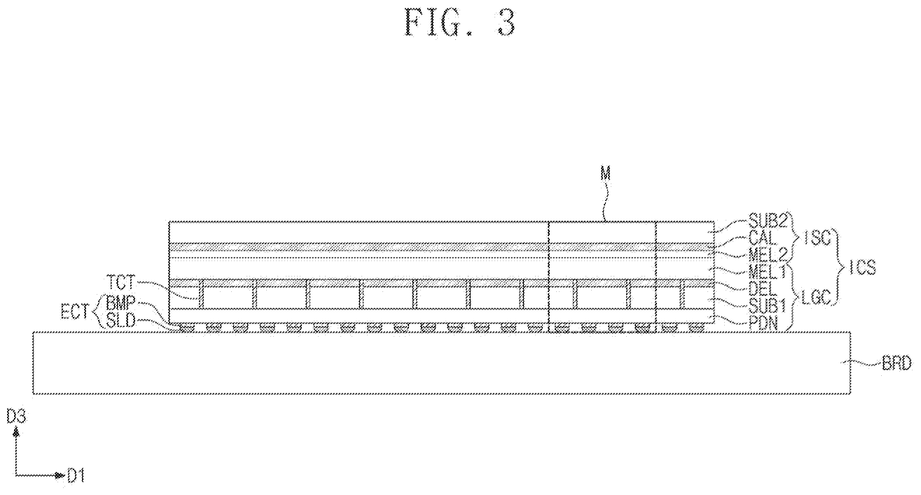

FIG. 3 illustrates a cross-sectional view showing a semiconductor package according to embodiments. FIG. 4 illustrates an enlarged cross-sectional view of section M shown in FIG. 3, showing a three-dimensional integrated circuit structure according to embodiments.

Referring to FIG. 3, there may be provided a three-dimensional integrated circuit structure ICS on a package substrate BRD. In embodiments, the three-dimensional integrated circuit structure ICS may include first and second dies LGC and ISC that are stacked. The second die ISC may be stacked on the first die LGC.

The first die LGC may be a semiconductor chip that is disposed at a bottom tier of the three-dimensional integrated circuit structure ICS. In embodiments, the first die LGC may be the logic die LGC discussed above with reference to FIGS. 1 and 2A to 2E. The second die ISC may be a semiconductor chip that is disposed at a top tier of the three-dimensional integrated circuit structure ICS. In embodiments, the second die ISC may be a capacitor die.

A plurality of external connection members ECT may be provided between the three-dimensional integrated circuit structure ICS and the package substrate BRD. An external connection member ECT may include a bump pattern BMP connected to the power delivery network PDN of the logic die LGC, and a solder pattern SLD on the bump pattern BMP. The three-dimensional integrated circuit structure ICS may be connected through the external connection members ECT to the package substrate BRD. Power may be applied from the package substrate BRD through the external connection members ECT to the three-dimensional integrated circuit structure ICS.

The logic die LGC may include a first substrate SUB1. The logic die LGC may include a power delivery network PDN on a second surface SUB1b of the first substrate SUB1. The logic die LGC may include a first wiring layer MEL1 and a device layer DEL on a first surface SUB1a of the first substrate SUB1.

The logic die LGC may include through contacts TCT that extend in a third direction D3 from the power delivery network PDN to the first wiring layer MEL1. Power may be transferred from the power delivery network PDN via the through contacts TCT to the device layer DEL.

The capacitor die ISC may include a second substrate SUB2. The second substrate SUB2 may have a first surface SUB2a and a second surface SUB2b. The second surface SUB2b may stand opposite to the first surface SUB2a. The second surface SUB2b of the second substrate SUB2 may be a top surface of the three-dimensional integrated circuit structure ICS, and the top surface may be externally exposed.

The capacitor die ISC may include a capacitor layer CAL on the first surface SUB2a of the second substrate SUB2. The capacitor die ISC may include a second wiring layer MEL2 on the capacitor layer CAL. The second wiring layer MEL2 may face and contact the first wiring layer MEL1 of the logic die LGC. The first wiring layer MEL1 of the logic die LGC may be electrically connected to the second wiring layer MEL2 of the capacitor die ISC.

With reference to FIGS. 3 and 4, the following will describe in detail an internal structure of the three-dimensional integrated circuit structure ICS. The power delivery network PDN of the logic die LGC may include pads PAD disposed in a lowermost portion of the power delivery network PDN. The pads PAD may be correspondingly provided thereon with external connection members ECT. Power may be applied to the external connection members ECT to the power delivery network PDN.

The device layer DEL of the logic die LGC may include a front-end-of-line (FEOL) layer formed by a front-end-of-line process of semiconductor fabrication. The device layer DEL may include transistors and contacts AC and GC discussed above with reference to FIGS. 1 and 2A to 2D. For example, the device layer DEL may include source/drain patterns SD and gate electrodes GE that constitute transistors. The device layer DEL may include active contacts AC coupled to corresponding source/drain patterns SD.

A first wiring layer MEL1 may be provided on the device layer DEL. The first wiring layer MEL1 may include first, second, third, and fourth metal layers M1, M2, M3, and M4 that are sequentially stacked. Each of the first to fourth metal layers M1 to M4 may include lines and vias.

The through contact TCT may penetrate the first substrate SUB1 and the device layer DEL to electrically connect the power delivery network PDN to the first metal layer M1. Power may be transferred from the power delivery network PDN to the device layer DEL via the through contact TCT and the first metal layer M1.

The first wiring layer MEL1 may include connection pads BPD at an uppermost portion thereof. For example, the connection pads BPD may be provided on the fourth metal layer M4. The connection pads BPD may include metal, such as copper. The connection pads BPD may serve as connection pads for electrical connection to a capacitor die ISC.

The capacitor die ISC may be face-down stacked on the logic die LGC. The following will describe in detail the capacitor die ISC. The second substrate SUB2 may have a first surface SUB2a and a second surface SUB2b that are opposite to each other. The first surface SUB2a may be a top surface or a front side of the second substrate SUB2, and the second surface SUB2b may be a bottom surface or a back side of the second substrate SUB2. The second surface SUB2b of the second substrate SUB2 may be a top surface of the three-dimensional integrated circuit structure ICS, and the top surface may be externally exposed.

A dielectric layer IL may be provided on the first surface SUB2a of the second substrate SUB2. The dielectric layer IL may be directly formed on the first surface SUB2a. A capacitor layer CAL may be provided on the dielectric layer IL.

The capacitor layer CAL may include a capacitor CAP and a first interlayer dielectric layer 210 on the dielectric layer IL. A plurality of holes DHO may be formed in the first interlayer dielectric layer 210. Each of the holes DHO may have a diameter that gradually decreases with decreasing distance from the second substrate SUB2.

The capacitor CAP may include a bottom electrode BEL, and may also include a first electrode EL1, a dielectric layer DIL, a second electrode EL2, and a top electrode TEL that are sequentially stacked on the bottom electrode BEL. The bottom electrode BEL may be provided on a top surface of the dielectric layer IL. The bottom electrode BEL may have a second-dimensional plate shape. The first interlayer dielectric layer 210 may be formed on the bottom electrode BEL.

The first electrode EL1, the dielectric layer DIL, the second electrode EL2, and the top electrode TEL may be provided in the hole DHO of the first interlayer dielectric layer 210. Each of the first electrode EL1, the dielectric layer DIL, and the second electrode EL2 may have a regular thickness in the hole DHO. The first electrode EL1, the dielectric layer DIL, and the second electrode EL2 may not completely fill, but may partially fill the hole DHO. The top electrode TEL may completely fill the hole DHO. The first electrode EL1, the dielectric layer DIL, the second electrode EL2, and the top electrode TEL may be provided also on a top surface of the first interlayer dielectric layer 210.

The first electrode EL1 may be electrically connected to the bottom electrode BEL. The second electrode EL2 may be electrically connected to the top electrode TEL. A first voltage may be applied through the bottom electrode BEL to the first electrode EL1, and a second voltage may be applied through the top electrode TEL to the second electrode EL2.

A second wiring layer MEL2 may be provided on the capacitor layer CAL. The second wiring layer MEL2 may include a second interlayer dielectric layer 220. The second interlayer dielectric layer 220 may be provided on the first interlayer dielectric layer 210, covering an upper portion of the capacitor CAP.

The second wiring layer MEL2 may include, in the second interlayer dielectric layer 220, first and second vias VI1 and VI2 and first and second power lines POL1 and POL2. The first power line POL1 may be connected through the first via VI1 to the top electrode TEL. Because the top electrode TEL is in contact with the second electrode EL2, the first power line POL1 may be electrically connected to the second electrode EL2.

The second power line POL2 may be connected through the second via VI2 to the bottom electrode BEL. Because the bottom electrode BEL is in contact with the first electrode EL1, the second power line POL2 may be electrically connected to the first electrode EL1.

In embodiments, the first power line POL1 may be supplied with a power voltage (VDD), and the second power lines POL2 may be supplied with a ground voltage (VSS). Power including the power voltage (VDD) and the ground voltage (VSS) may be transferred to the first and second power lines POL1 and POL2 through the first wiring layer MEL1 of the logic die LGC.

Each of the first and second electrodes EL1 and EL2 may include conductive metal nitride, such as TiN or TaN. The dielectric layer DIL may include a high-k dielectric material such as hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or a combination thereof. The top electrode TEL may include a semiconductor material, for example, polysilicon. The bottom electrode BEL may include a semiconductor material or a metallic material, such as titanium (Ti), tantalum (Ta), aluminum (Al), tungsten (W), or molybdenum (Mo).

The first and second power lines POL1 and POL2 of the second wiring layer MEL2 may be in contact with the connection pads BPD of the first wiring layer MEL1. In embodiments, the first and second power lines POL1 and POL2 may be coupled to the connection pads BPD. For example, a Cu—Cu bonding may be provided between the connection pads BPD and the first and second power lines POL1 and POL2.

The three-dimensional integrated circuit structure ICS according to embodiments may include the logic die LGC that includes a backside power delivery network PDN and may also include the capacitor die ISC that is face-down stacked on the logic die LGC. Power may be transferred in the third direction D3 perpendicular to the power delivery network PDN, and may be directly transmitted to the device layer DEL of the logic die LGC and to the capacitor layer CAL of the capacitor die ISC. Because the three-dimensional integrated circuit structure ICS is configured to directly transfer power in a vertical direction to the logic die LGC and the capacitor die ISC, a power transmission efficiency may be increased to improve electrical properties.

An integrated stacked capacitor may be included in the capacitor die ISC of the three-dimensional integrated circuit structure ICS, and thus the capacitor die ISC may have an increased capacitance and improved electrical properties. Because the first wiring layer MEL1 of the logic die LGC and the second wiring layer MEL2 of the capacitor die ISC are connected while being in direct contact with each other, signals may be promptly transmitted between the logic die LGC and the capacitor die ISC. In conclusion, the three-dimensional integrated circuit structure ICS may increase signal processing speed.

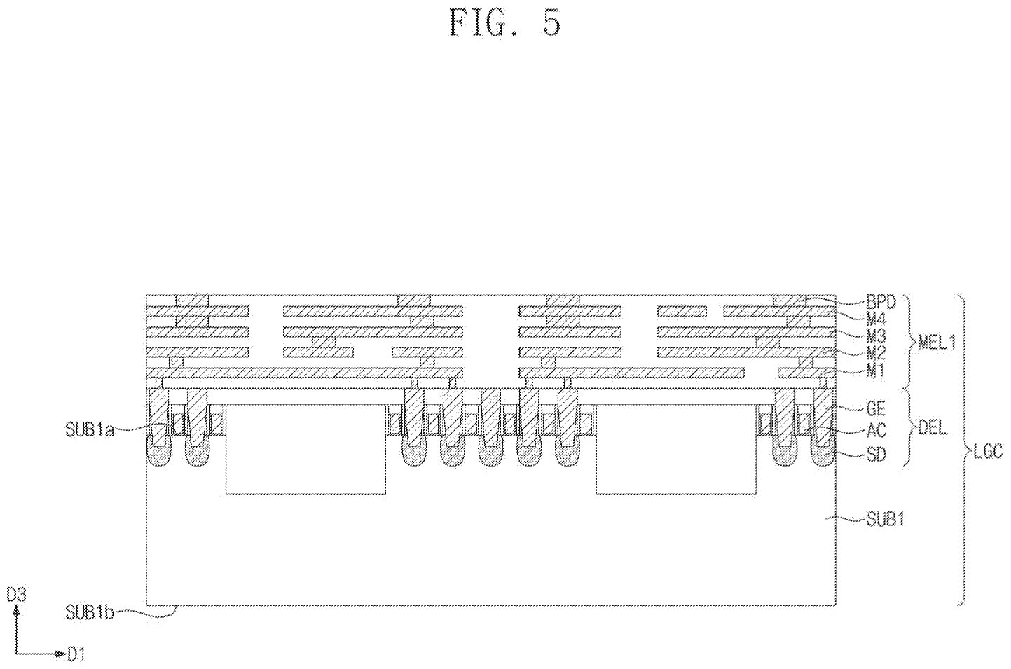

FIGS. 5 to 8 illustrate cross-sectional views of section M shown in FIG. 3, showing a method of fabricating a three-dimensional integrated circuit structure, according to embodiments.

Referring to FIG. 5, a front-end-of-line (FEOL) process for the manufacturing of semiconductor chips may be performed such that a device layer DEL may be formed on a first surface SUB1a of a first substrate SUB1. For example, a plurality of source/drain patterns SD may be formed on an upper portion of the first substrate SUB1. A plurality of gate electrodes GE may be formed on the first substrate SUB1. A plurality of active contacts AC may be formed for connection to corresponding source/drain patterns SD.

A back-end-of-line (BEOL) process for the manufacturing of semiconductor chips may be performed to form a first wiring layer MEL1 on the device layer DEL. For example, the formation of the first wiring layer MEL1 may include sequentially forming (or stacking) a plurality of first, second, third, and fourth metal layers M1, M2, M3, and M4. A plurality of connection pads BPD may be formed at an uppermost portion of the first wiring layer MEL1. A logic die LGC may be prepared through the FEOL and BEOL processes for the manufacturing of semiconductor chips.

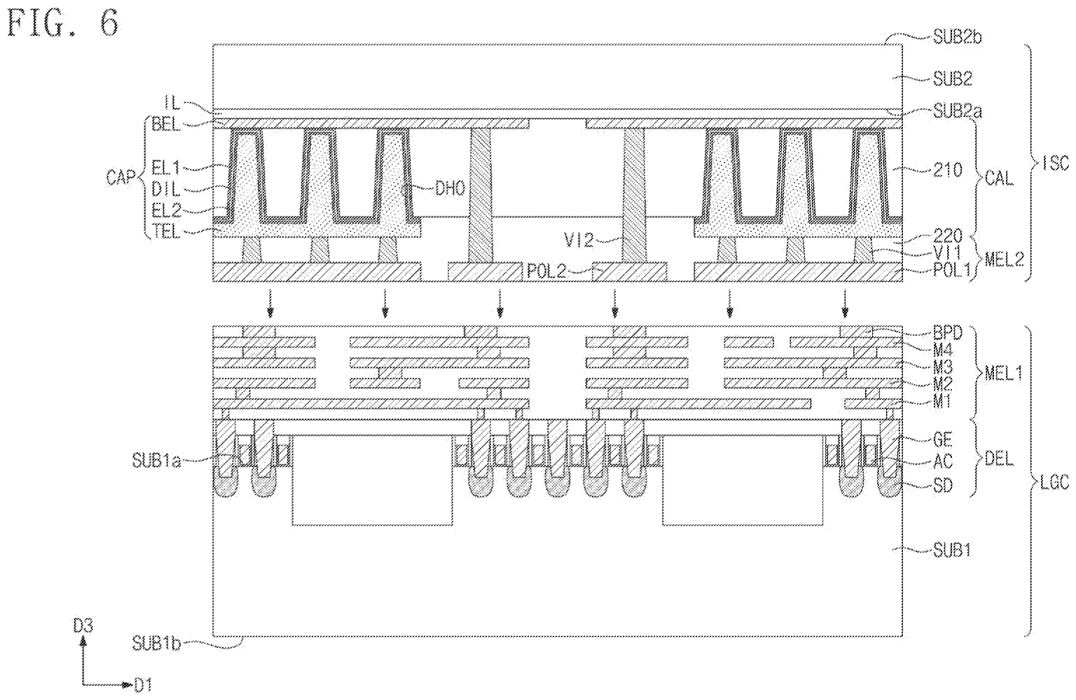

Referring to FIG. 6, a capacitor die ISC may be manufactured. For example, a dielectric layer IL may be formed on a first surface SUB2a of a second substrate SUB2. A capacitor layer CAL may be formed on the dielectric layer IL.

The following will describe in detail the formation of the capacitor layer CAL. A bottom electrode BEL may be formed on the dielectric layer IL. A first interlayer dielectric layer 210 may be formed on the bottom electrode BEL. A plurality of holes DHO may be formed to penetrate the first interlayer dielectric layer 210 to expose a top surface of the bottom electrode BEL. A first electrode EL1, a dielectric layer DIL, a second electrode EL2, and a top electrode TEL may be sequentially formed in the plurality of holes DHO to obtain a capacitor CAP.

A second interlayer dielectric layer 220 may be formed on the capacitor CAP. A second wiring layer MEL2 may be formed in the second interlayer dielectric layer 220. The formation of the second wiring layer MEL2 may include forming first and second vias VI1 and VI2 and forming first and second power lines POL1 and POL2.

The manufactured capacitor die ISC may be turned upside down to expose a second surface SUB2b of the second substrate SUB2. The capacitor die ISC may be face-down stacked on the logic die LGC, and thus the logic die LGC and the capacitor die ISC may be coupled to each other. For example, the first wiring layer MEL1 of the logic die LGC and the second wiring layer MEL2 of the capacitor die ISC may be directly coupled to each other through a Cu—Cu bonding.

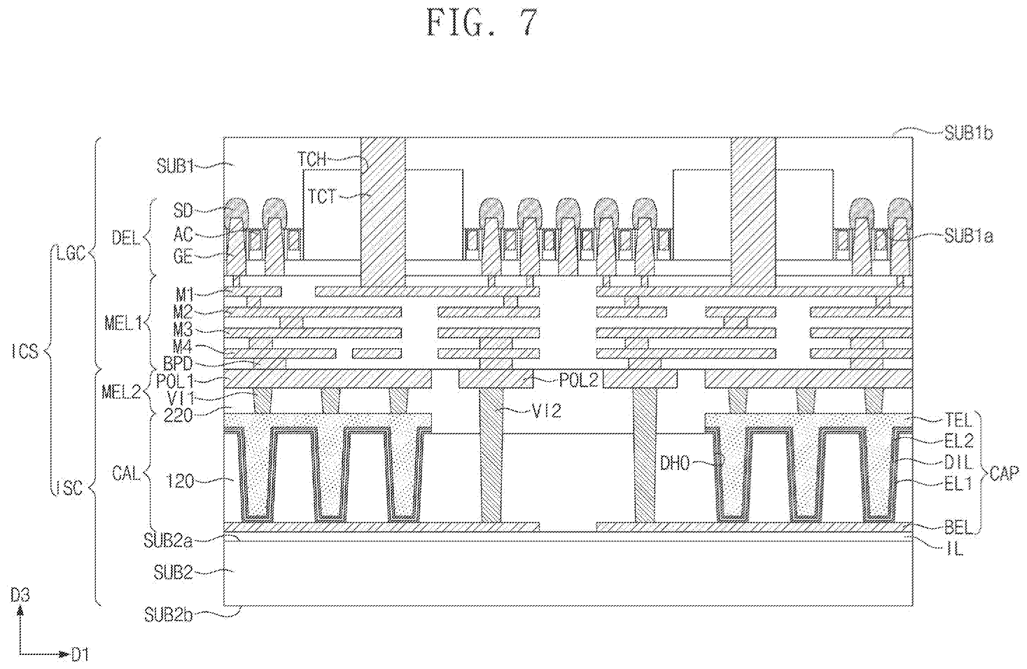

Referring to FIG. 7, as the capacitor die ISC is stacked on the logic die LGC, a three-dimensional integrated circuit structure ICS may be formed. The three-dimensional integrated circuit structure ICS may be turned upside down to expose a second surface SUB1b of the first substrate SUB1.

The second surface SUB1b of the first substrate SUB1 may undergo an anisotropic etching process to form a through contact hole TCH that penetrates the first substrate SUB1. The etching process may continue until the through contact hole TCH exposes the first metal layer M1. The through contact hole TCH may be filled with a conductive material to form a through contact TCT. The through contact TCT may be in direct contact with a power line of the first metal layer M1.

The second surface SUB1b of the first substrate SUB1 may undergo a chemical mechanical polishing (CMP) process to reduce a thickness of the first substrate SUB1. The CMP process may be performed such that a top surface of the through contact TCT may be exposed through the second surface SUB1b.

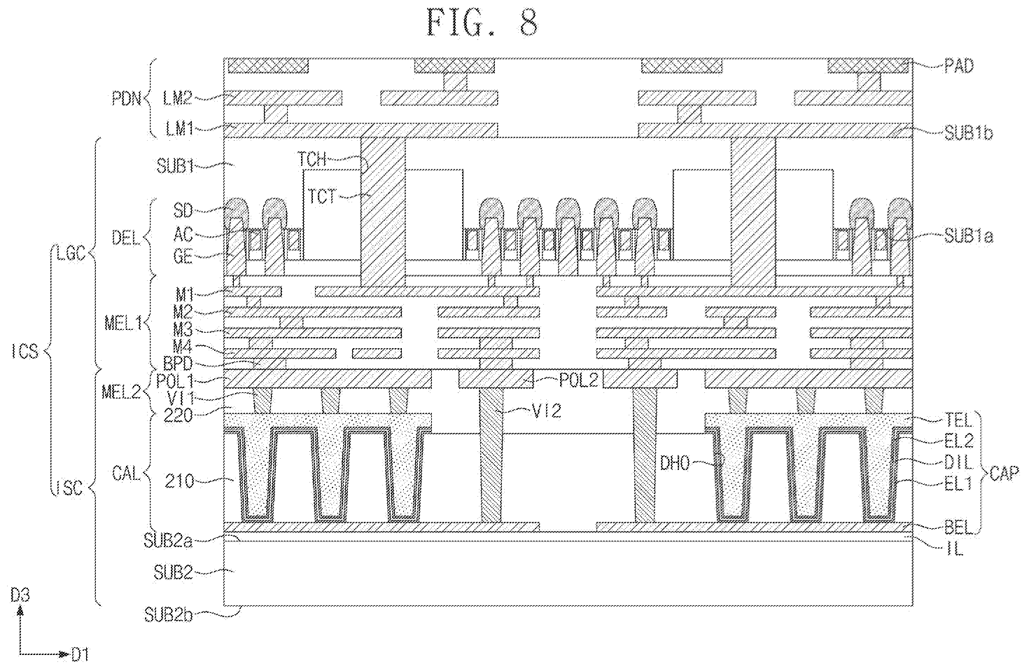

Referring to FIG. 8, a semiconductor process may be performed to form a power delivery network PDN on the second surface SUB1b of the first substrate SUB1. For example, first lower lines LM1 may be formed on the second surface SUB1b, and second lower lines LM2 may be formed on the first lower lines LM1. At least one of the first lower lines LM1 may be in contact with the through contact TCT. For example, the first lower line LM1 may be electrically connected via the through contact TCT to the first metal layer M1.

A plurality of pads PAD may be formed on the second lower lines LM2. The pads PAD may be exposed externally. The first and second lower lines LM1 and LM2 and the pads PAD may constitute a power delivery network PDN.

Referring back to FIG. 4, external connection members ECT may be correspondingly formed on the pads PAD. For example, a plating process may be performed to form a bump pattern BMP on the pad. A solder pattern SLD may be formed on the bump pattern BMP. As illustrated in FIG. 3, the manufactured three-dimensional integrated circuit structure ICS may be mounted on a package substrate BRD. The three-dimensional integrated circuit structure ICS may be used as a processor chip of a semiconductor package.

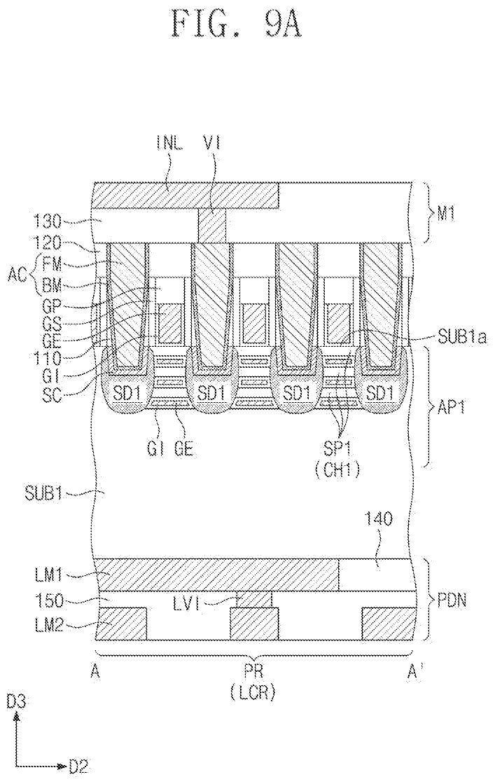

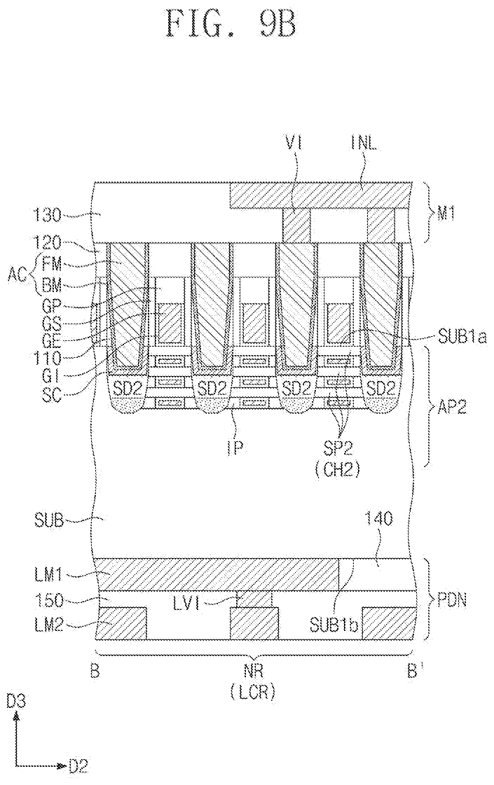

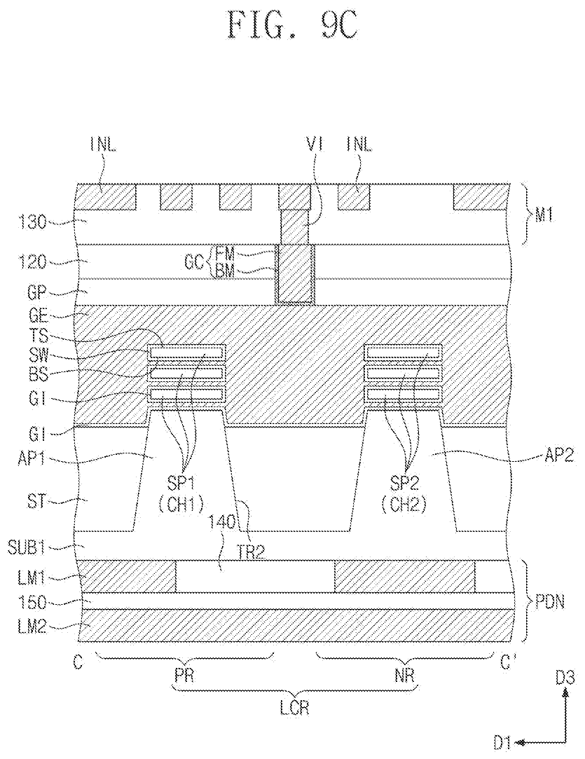

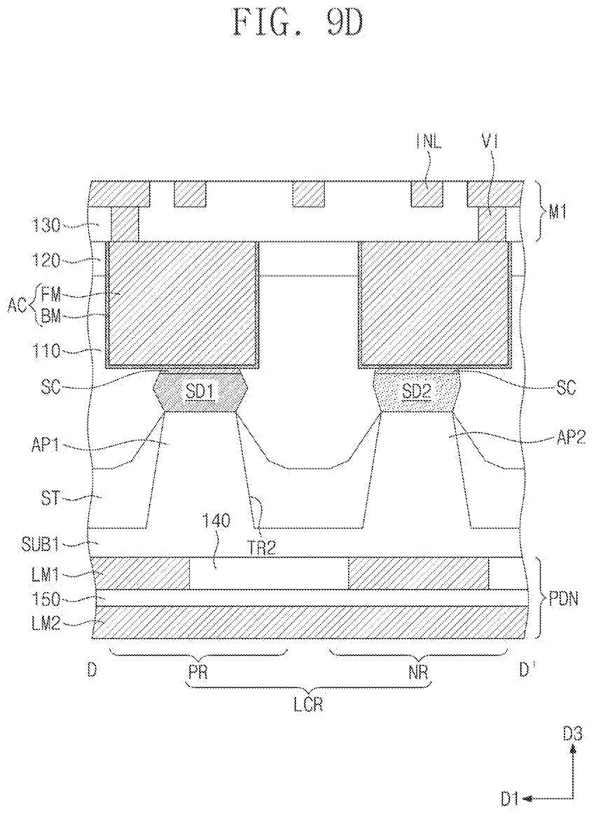

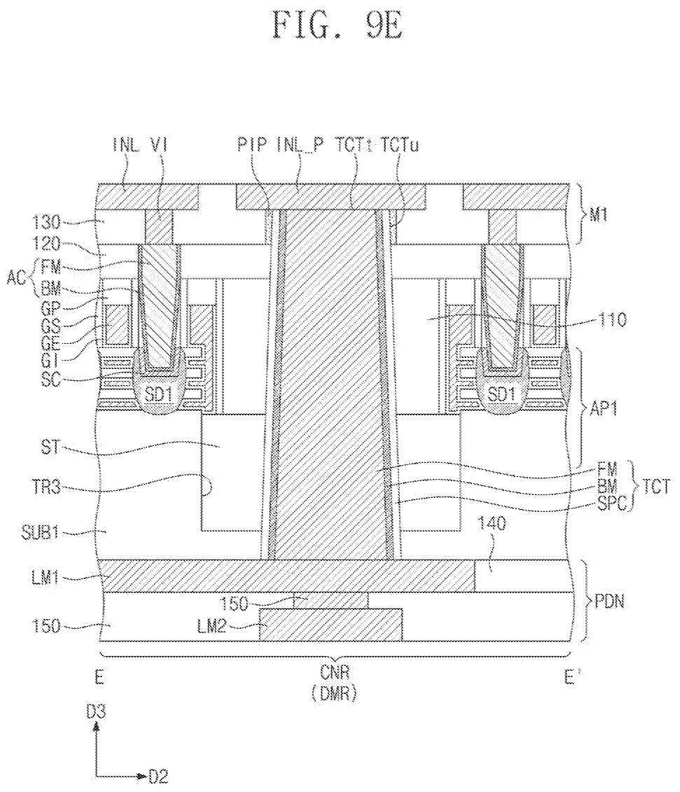

FIGS. 9A, 9B, 9C, 9D, and 9E illustrate cross-sectional views respectively taken along lines A-A′, B-B′, C-C′, D-D′, and E-E′ of FIG. 1, showing a logic die according to embodiments. In the embodiment that follows, a detailed description of technical features repetitive to those discussed above with reference to FIGS. 1 and 2A to 2E will be omitted, and a difference from that discussed above with reference to FIGS. 1 and 2A to 2E will be described in detail.

Referring to FIGS. 1 and 9A to 9E, a first substrate SUB1 may be provided to include a logic cell region LCR and a connection region CNR. For example, the logic cell region LCR may include a first active region PR and a second active region NR.

A device isolation layer ST may be provided on the first substrate SUB1. The device isolation layer ST may define a first active pattern AP1 and a second active pattern AP2 on an upper portion of the first substrate SUB1. The first active pattern AP1 and the second active pattern AP2 may be respectively defined on the first active region PR and the second active region NR.

The first active pattern AP1 and the second active pattern AP2 may respectively include a first channel pattern CH1 and a second channel pattern CH2. For example, the first channel pattern CH1 may include a plurality of first semiconductor patterns SP1 that are vertically stacked. The stacked first semiconductor patterns SP1 may be spaced apart from each other in a third direction D3. The stacked first semiconductor patterns SP1 may vertically overlap each other. The second channel pattern CH2 may include a plurality of second semiconductor patterns SP2 that are vertically stacked. The stacked second semiconductor patterns SP2 may be spaced apart from each other in the third direction D3. The stacked second semiconductor patterns SP2 may vertically overlap each other. The first and second semiconductor patterns SP1 and SP2 may include at least one of silicon (Si), germanium (Ge), and silicon-germanium (SiGe).

The first active pattern AP1 may further include first source/drain patterns SD1. The stacked first semiconductor patterns SP1 that constitute the first channel pattern CH1 may be interposed between a pair of neighboring first source/drain patterns SD1. The stacked first semiconductor patterns SP1 may connect the pair of neighboring first source/drain patterns SD1 to each other.

The second active pattern AP2 may further include second source/drain patterns SD2. The stacked second semiconductor patterns SP2 that constitute the second channel pattern CH2 may be interposed between a pair of neighboring second source/drain patterns SD2. The stacked second semiconductor patterns SP2 may connect the pair of neighboring second source/drain patterns SD2 to each other.

A plurality of gate electrodes GE may be provided to extend in a first direction D1 and to run across the first and second channel patterns CH1 and CH2. The gate electrode GE may vertically overlap the first and second channel patterns CH1 and CH2. A pair of gate spacers GS may be disposed on opposite sidewalls of the gate electrode GE. A gate capping pattern GP may be provided on the gate electrode GE.

Referring back to FIG. 9C, the gate electrode GE may surround the first and second semiconductor patterns SP1 and SP2. For example, the gate electrode GE may be provided on a top surface TS, at least one sidewall SW, and a bottom surface BS of an uppermost first semiconductor pattern SP1. For example, the gate electrode GE may be formed on top and bottom surfaces and opposite sidewalls of each of the first and second semiconductor patterns SP1 and SP2. A transistor according to the present embodiment may be a three-dimensional field effect transistor (e.g. MBCFET, nanosheet transistor or GAAFET) in which the gate electrode GE three-dimensionally surrounds the first and second channel patterns CH1 and CH2.

Referring back to FIGS. 1 and 9A to 9E, a gate dielectric layer GI may be provided between the gate electrode GE and each of the first and second channel patterns CH1 and CH2. The gate dielectric layer GI may be formed on the first and second semiconductor patterns SP1 and SP2.

On the second active region NR, a dielectric pattern IP may be interposed between the gate dielectric layer GI and the second source/drain pattern SD2. The gate dielectric layer GI and the dielectric pattern IP may separate the gate electrode GE from the second source/drain pattern SD2. In contrast, the dielectric pattern IP may be omitted from the first active region PR.

A first interlayer dielectric layer 110 and a second interlayer dielectric layer 120 may be provided on a front side of the first substrate SUB1. Active contacts AC may be provided to penetrate the first and second interlayer dielectric layers 110 and 120 to be correspondingly connected to the first and second source/drain patterns SD1 and SD2. A gate contact GC may be provided to penetrate the second interlayer dielectric layer 120 and the gate capping pattern GP to be electrically connected to the gate electrode GE. A detailed description of the active contacts AC and the gate contacts GC may be substantially the same as that discussed above with reference to FIGS. 1 and 2A to 2D.

A third interlayer dielectric layer 130 may be provided on the second interlayer dielectric layer 120. A first metal layer M1 may be provided in the third interlayer dielectric layer 130. A power delivery network PDN may be provided on a back side of the first substrate SUB1.

A through contact TCT may be provided on the connection region CNR. The through contact TCT may penetrate the first substrate SUB1. The through contact TCT may vertically extend from the power delivery network PDN to the first metal layer M1. A detailed description of the through contact TCT may be substantially the same as that discussed above with reference to FIGS. 1 and 2E.

A three-dimensional integrated circuit structure according to the above embodiments may include a logic die that includes a backside power delivery network, and may also include a capacitor die that is wafer-bonded to the logic die. Power applied to the power delivery network may be directly transferred to the logic die and the capacitor die. A first wiring layer of the logic die and a second wiring layer of the capacitor die may be connected to each other while being in direct contact with each other, and thus signals may be promptly transmitted between the logic die and the capacitor die. For example, signals may be transmitted along a shortest path between a logic circuit of the logic die and a capacitor of the capacitor die. As a result, the three-dimensional integrated circuit structure may increase signal processing speed and may improve in electrical properties.

It is noted here that although the disclosure is described through the above embodiments in which a logic die including three-dimensional transistors and a capacitor die including capacitors are coupled to each other, the disclosure is not limited thereto. According to embodiments, an active device die including other types of active devices or other types of transistors may replace the logic die LGC, and a passive device die including other types of passive devices such as resistors, inductors, etc. may replace the capacitor die ISC to implement the disclosure.

Although various embodiments have been discussed with reference to accompanying figures, it will be understood that various changes in form and details may be made therein without departing from the spirit and scope of the disclosure. It therefore will be understood that the embodiments described above are just illustrative but not limitative in all aspects.

What is claimed is:

1. A three-dimensional integrated circuit structure comprising:
an active device die; and
a passive device die stacked on the active device die,
wherein the active device die comprises:
a first substrate comprising a front side and a back side that are opposite to each other;
a power delivery network on the back side of the first substrate;
a device layer on the front side of the first substrate;
a first wiring layer on the device layer; and
a through contact that vertically extends from the power delivery network to the first wiring layer,
wherein the passive device die comprises:
a second substrate comprising a front side and a back side that are opposite to each other, the front side of the second substrate facing the front side of the first substrate;
an interlayer dielectric layer on the front side of the second substrate, the interlayer dielectric layer comprising at least one hole;
a passive device in the hole; and
a second wiring layer on the passive device, and
wherein the second wiring layer faces and is connected to the first wiring layer.

2. The structure of claim 1, further comprising an external connection member beneath the power delivery network for applying power to the power delivery network.

3. The structure of claim 2, wherein the through contact is configured to transmit the power applied to the power delivery network to the first wiring layer and the second wiring layer, and
wherein the first wiring layer is configured to apply the transmitted power to the device layer, and the second wiring layer is configured to apply the transmitted power to the passive device.

4. The structure of claim 1, wherein the device layer comprises a plurality of transistors that constitute a logic circuit, and
wherein the first and second wiring layers are configured to vertically transmit a signal between the logic circuit and the passive device.

5. The structure of claim 1, wherein the passive device comprises a capacitor comprising:
a bottom electrode on the front side of the second substrate, the bottom electrode being exposed through the hole; and
a first electrode, a dielectric layer, a second electrode, and a top electrode that are sequentially stacked in the hole,
wherein a bottom portion of the first electrode is in contact with the bottom electrode,
wherein the top electrode is electrically connected to a first power line of the second wiring layer, and
wherein the bottom electrode is electrically connected to a second power line of the second wiring layer.

6. The structure of claim 5, wherein each of the first electrode and the second electrode has a cylindrical shape that corresponds to a profile of the hole.

7. The structure of claim 1, wherein a connection pad at top of the first wiring layer is directly coupled to an uppermost line of the second wiring layer.

8. The structure of claim 1, wherein the first substrate comprises a logic cell region and a dummy cell region; and
wherein the through contact penetrates the dummy cell region.

9. The structure of claim 1, wherein a lower portion of the through contact is in contact with a lower line of the power delivery network, and
wherein an upper portion of the through contact is in contact with a power line of the first wiring layer.

10. The structure of claim 9, wherein a width of the lower portion of the through contact is greater than a width of the upper portion of the through contact.

11. A three-dimensional integrated circuit structure comprising:
a first die comprising a power delivery network, a first substrate, a device layer, and a first wiring layer that are sequentially stacked;
a second die on the first die, the second die comprising a second wiring layer, a capacitor layer, and a second substrate that are sequentially stacked on the first wiring layer;
a through contact that vertically extends from the power delivery network to the first wiring layer; and
an external connection member beneath the power delivery network,
wherein a lower portion of the through contact is in contact with a lower line of the power delivery network,
wherein an upper portion of the through contact is in contact with a power line of the first wiring layer,
wherein a width of the lower portion of the through contact is greater than a width of the upper portion of the through contact, and
wherein the power delivery network, the through contact, the first wiring layer and the second wiring layer are configured to vertically transmit power from the external connection member to the capacitor layer.

12. The structure of claim 11, wherein the device layer comprises a plurality of transistors that constitute a logic circuit,
wherein the capacitor layer comprises an interlayer dielectric layer and a capacitor that penetrates the interlayer dielectric layer, and
wherein the plurality of transistors and the capacitor are electrically connected to each other through the first and second wiring layers.

13. The structure of claim 12, wherein the capacitor comprises a first electrode, a dielectric layer, and a second electrode that are sequentially stacked on an inner sidewall of a hole that penetrates the interlayer dielectric layer.

14. The structure of claim 11, wherein the external connection member comprises:
a bump pattern on a pad of the power delivery network; and
a solder pattern on the bump pattern.

15. The structure of claim 11, wherein a top surface of the through contact is in direct contact with a bottom surface of the power line.

16. A three-dimensional integrated circuit structure comprising:
a power delivery network that comprises a plurality of stacked lower lines;
a first semiconductor substrate on the power delivery network;
a plurality of transistors that are on the first semiconductor substrate and constitute a logic circuit;
a first wiring layer that comprises a plurality of metal layers on the plurality of transistors;
a through contact that electrically connects the power delivery network to a first metal layer of the plurality of metal layers, the through contact penetrating the first semiconductor substrate and vertically extending;
a second wiring layer on the first wiring layer;
a capacitor layer on the second wiring layer, the capacitor layer comprising an interlayer dielectric layer and a capacitor that penetrates the interlayer dielectric layer; and
a second semiconductor substrate on the capacitor layer,
wherein the plurality of transistors and the capacitor are electrically connected to each other through the first and second wiring layers.

17. The structure of claim 16, wherein the through contact is configured to transmit power from the power delivery network to a power line of the first metal layer.

18. The structure of claim 16, wherein the capacitor comprises a first electrode, a dielectric layer, and a second electrode that are sequentially stacked on an inner sidewall of a hole that penetrates the interlayer dielectric layer.

19. The structure of claim 16, wherein the first wiring layer and the second wiring layer are directly coupled to each other.

20. The structure of claim 16, wherein a lower portion of the through contact is in contact with a lower line of the power delivery network,
wherein an upper portion of the through contact is in contact with the first metal layer, and
wherein a width of the lower portion of the through contact is greater than a width of the upper portion of the through contact.
